(19) United States
(12) Patent Application Publication
(10) Pub. No.: US 2026/0018202 A1
(43) Pub. Date: Jan. 15, 2026

(54) BUS SHARING FOR ROW HAMMER MITIGATION ALERT

(71) Applicant: Micron Technology, Inc., Boise, ID (US)

(72) Inventors: Hiroshi Akamatsu, Boise, ID (US); Yuan He, Boise, ID (US)

(73) Assignee: Micron Technology, Inc., Boise, ID (US)

(21) Appl. No.: 19/261,367

(22) Filed: Jul. 7, 2025

Related U.S. Application Data
(60) Provisional application No. 63/669,160, filed on Jul. 9, 2024.

(51) Int. Cl. G11C 11/406; G11C 11/4072; G11C 11/4096

(52) U.S. Cl. CPC G11C 11/40622; G11C 11/40603; G11C 11/4072; G11C 11/4096

(57) ABSTRACT

Systems, apparatuses and methods for a shared unilateral bus used to transmit a command from a controller to a memory and to transmit a targeted refresh alert from a memory device to a controller. The memory includes a shared bus logic circuit to manage the transmission of targeted refresh alerts and the reception of commands on the shared bidirectional bus. The controller also includes a shared bus logic circuit to manage the transmission of commands and the reception of targeted refresh alerts from one or more memory devices coupled to the controller with one or more shared bidirectional buses. Each of the one or more shared bidirectional buses may transmit a different command to the one or more memory devices, such as a reset command or a calibration command.

### CROSS-REFERENCE TO RELATED APPLICATIONS

This application claims the filing benefit of U.S. Provisional Application No. 63/669,160, filed Jul. 9, 2024. This application is incorporated by reference herein in its entirety and for all purposes.

### BACKGROUND

This disclosure relates generally to semiconductor devices, and more specifically to semiconductor memory devices. In particular, the disclosure relates to volatile memory, such as dynamic random access memory (DRAM). Information is stored in the memory on memory cells as a physical signal, such as a charge on a capacitive element. Information may decay over time in the memory cells. For example, the memory cells may discharge over time. In order to preserve the integrity of the stored information, the memory cells may be refreshed, for example to restore an initial charge level associated with the stored information.

Certain patterns of access may cause an increased rate of information decay in nearby memory cells (e.g., the memory cells along nearby word lines). Memory devices may use various schemes to identify these access patterns so that targeted refresh operations may be performed. To initiate targeted refresh operations, the memory device may send an alert to a controller.

### BRIEF DESCRIPTION OF DRAWINGS

FIG. 1 is a block diagram of a system according to at least one embodiment of the disclosure.

FIG. 2 is a block diagram of a semiconductor device according to at least one embodiment of the disclosure.

FIG. 3 is a schematic diagram of a shared bus RHR logic circuit that may be included on a memory device according to at least one embodiment of the disclosure.

FIG. 4 is a schematic diagram of a shared bus RHR logic circuit that may be included on a controller according to at least one embodiment of the disclosure.

FIG. 5 is a timing diagram of example behaviors of signals according to at least one embodiment of the disclosure.

FIG. 6 is a block diagram of a system according to at least one embodiment of the disclosure.

FIG. 7 is a block diagram of an arbiter circuit according to some embodiments of the present disclosure.

FIG. 8 is a timing diagram of example behaviors of signals according to at least one embodiment of the disclosure.

FIG. 9 is a block diagram of a refresh management (RFM) logic circuit according to some embodiments of the present disclosure.

FIG. 10 is a flow chart of a method according to some embodiments of the present disclosure.

FIG. 11 is a flow chart of a method according to some embodiments of the present disclosure.

### DETAILED DESCRIPTION

Certain details are set forth below to provide a sufficient understanding of examples of the disclosure. However, it will be clear to one having skill in the art that examples of the disclosure may be practiced without these particular details. Moreover, the particular examples of the present disclosure described herein should not be construed to limit the scope of the disclosure to these particular examples. In other instances, well-known circuits, control signals, timing protocols, and software operations have not been shown in detail in order to avoid unnecessarily obscuring the disclosure. Additionally, terms such as “couples” and “coupled” mean that two components may be directly or indirectly electrically coupled. Indirectly coupled may imply that two components are coupled through one or more intermediate components.

Information in memory arrays included on memory devices may be accessed by one or more access operations, such as read or write operations. During an example access operation a word line may be activated based on a row address. Selected memory cells along that active word line may then have information read from or written to based on which bit lines are selected. The bit lines may be selected according to a column address. The memory array may be refreshed on a row by row basis (e.g., as part of an auto-refresh and/or self-refresh mode) where the memory cells along each row are refreshed periodically. The rows may be refreshed as part of a normal refresh or a self-refresh mode. The speed at which the rows are refreshed (e.g., the maximum time any given row will go between refreshes) may be determined based on an expected rate of information decay. In other words, the maximum time any given row goes between refreshes is calculated to be less than the expected amount of time it takes for the information in the row to decay.

Various patterns of access to a row (e.g., an aggressor row) may cause an increased rate of information decay in nearby memory cells (e.g., along victim rows). For example, a “row hammer” may involve repeated accesses to the aggressor row which may increase a rate of decay in adjacent rows (and/or in rows which are further away). Accordingly, the memory array may track a number of accesses to each row to determine if rows are aggressors, such that the victim rows can be identified and refreshed as part of a targeted refresh operation.

During targeted refresh operations, the memory device may need to signify to the controller to transmit refresh commands to the memory device. The memory device may be connected to the controller via multiple buses. Each bus may be a conductive element that couples corresponding terminals or “pins” of the memory device(s) and the controller. The bus may carry signals as voltages along the conductive element. There may be multiple buses to carry multiple types of signals, such as a command/address bus, a data bus, a clock bus, and the like. Some of the buses may be unidirectional, meaning that the bus only carries signals in one direction. For example, a unilateral bus may only carry signals transmitted from the controller to the memory device. Some buses may be bidirectional, meaning that they carry signals in two directions. For example, the controller and the memory device may use a bidirectional bus to transmit and receive signals to and from each other.

The controller may use the buses to send signals to the memory device indicating operations the memory device should perform. These signals from the controller to the memory device may be commands. The memory device may use the buses to send alerts or signals to the controller to indicate a status of the memory device or to request a command. For example, the memory device may transmit a refresh alert to the controller requesting a refresh command. It may be useful to use an existing bus to carry the refresh alert in order to avoid adding additional buses.

The present disclosure is drawn to apparatuses, systems, and methods for transmitting a targeted refresh alert on a bus that is also used to transmit a command. In other words, the bus is shared by the targeted refresh alert and the other command that uses the bus for transmission. The shared bus is bidirectional. The shared bus carries the targeted refresh alert transmitted from the memory device to the controller and carries the command transmitted from the controller to the memory device. The shared bidirectional bus is used to carry a command from the controller to the memory device and a targeted refresh alert from the memory device to the controller. In some embodiments, the command may be a reset command. In a conventional memory device, the reset command may be carried along a first unidirectional bus and the targeted refresh alert may be carried along a second separate bus.

In order to prevent conflicts, the controller and the memory device may include respective shared bus logic to manage the different signals. The shared bus logic may give some signals priority over other signals along the bus. In an example implementation where the bus is used for both the targeted refresh alert and the reset command, the reset command may have higher priority than the targeted refresh alert. For example, when the memory shared bus logic is providing the targeted refresh alert along the shared bus, if the controller begins providing a reset command along the shared bus, the reset command may override the targeted refresh alert and be passed through the memory shared bus logic to reset logic of the memory.

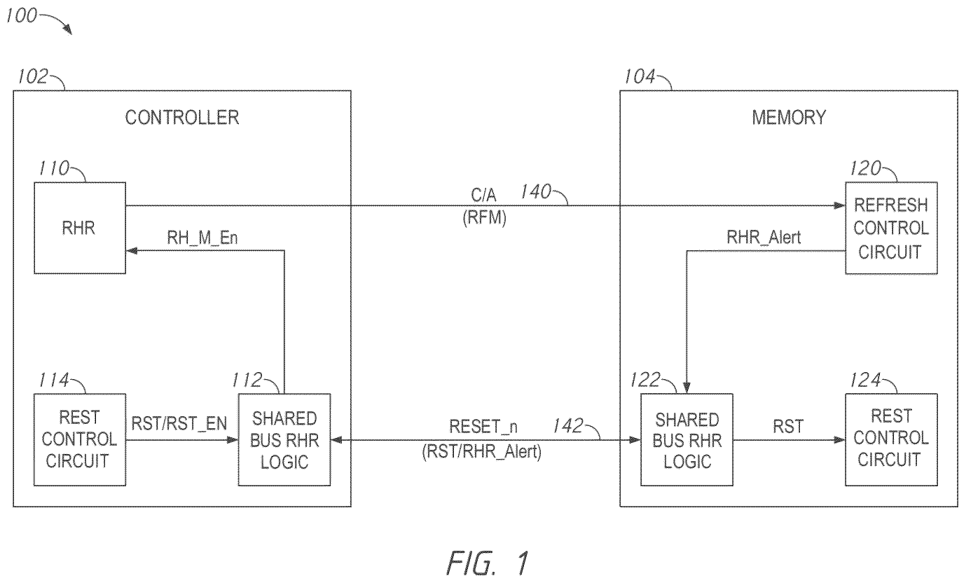

FIG. 1 is a block diagram of a system according to at least one embodiment of the disclosure. The system 100 includes a controller 102 and a memory device 104. The memory device 104 may be dynamic random access memory (DRAM), such as low power double data rate (LPDDR) DRAM, in some embodiments of the disclosure. The controller 102 and the memory device 104 are in communication over several buses. For example, command/address (C/A) buses, data buses (not shown), and/or clock buses (not shown) may couple the memory device 104 with the controller 102. The controller 102 may transmit commands to the memory device 104 and responsive to the transmitted commands, the memory device 104 may perform operations. In some embodiments, the controller 102 may transmit commands, such as refresh management (RFM) commands, to the memory device 104 on a command/address (C/A) bus 140. Other buses may also couple the controller 102 with the memory device 104 to carry other types of signals, for example a reset bus or a calibration bus to carry reset command or calibration commands, respectively. In some embodiments, a reset bus RESET_n may couple the controller 102 and the memory device 104 and be used to transmit a reset command RST from the controller to the memory. Some of the buses may be bidirectional buses that carry more than one signal in more than one direction. The system 100 may include a shared bidirectional bus 142 coupling the controller 102 to the memory 104 that carries alerts from the memory 104 to the controller 102 and also carries commands from the controller 102 to the memory 104. Each of the buses may include one or more signal lines on which signals are provided. For example, the shared bidirectional bus may include a single conductive element (e.g., the bus has width of one bit). In some embodiments, the C/A bus 140 may include more signal lines than the shared bidirectional bus 142. For example, the shared bidirectional bus 142 may be a single signal line while the C/A bus 140 includes multiple signal lines.

The controller 102 may include an RHR circuit 110. The RHR circuit 110 may transmit RFM commands to the memory device 104 that cause the memory device 104 to perform targeted refresh operations. For example, the RHR circuit 110 may transmit the RFM command to the memory device 104 via the command/address (C/A) bus 140. The memory device 104 may carry out targeted refresh operations, responsive to the RFM command. The controller 102 may transmit the RFM command responsive to a signal received from the memory device 104. For example, the memory device 104 may transmit an alert, such as a targeted refresh alert RHR_Alert, to the controller 102 when the memory device 104 determines that it should perform targeted refresh operations. Responsive to the targeted refresh alert RHR_Alert, the controller 102 may issue the RFM command to the memory device 104.

The controller 102 may include a shared bus RHR logic circuit 112. The shared bus RHR logic circuit 112 may, in some embodiments, manage multiple signals transmitted on a bidirectional bus. In other words, the bidirectional bus is used for at least one alert which goes from the memory device 104 to the controller 102 and at least one command which goes from the controller 102 to the memory device 104. For example, the system 100 may include a shared bidirectional bus 142 that couples the controller 102 with the memory device 104. The controller 102 may transmit commands on the shared bidirectional bus 142 to the memory device 104 and the memory device 104 may also transmit alerts on the shared bidirectional bus 142 to the controller 102. In some embodiments, the shared bidirectional bus 142 may be a RESET_n bus and the controller 102 may use it to transmit a reset command RST to the memory device 104. The controller 102 may transmit the reset command RST to the memory device 104 to reset the memory. The memory device may also use the shared bidirectional bus RESET_n to transmit a targeted refresh alert RHR_Alert to the controller when the memory device 104 determines that it should perform a targeted refresh operation.

The shared bidirectional bus 142 may be coupled to the shared bus RHR logic circuit 112 on the controller 102. The shared bus RHR logic circuit 112 may contain logic to prioritize the signals transmitted and received by the controller 102 on the shared bidirectional bus 142. For example, when the memory device 104 is providing the targeted refresh alert RHR_Alert along the shared bidirectional bus 142, if the controller 104 begins providing a reset command RST along the shared bidirectional bus 142, the reset command RST may override the targeted refresh alert RHR_Alert.

The reset command RST may originate from a reset control circuit 114 included in the controller 102. The reset control circuit 114 may contain logic to reset the memory device 104 by transmitting the reset command RST and a reset enable signal RST_EN to the shared bus RHR logic circuit 112 of the controller 102. Based on these signals, the shared bus RHR logic circuit 112 of the controller 102 then passes the reset command RST to the memory device 104 to initiate a reset operation. In some embodiments, the reset command RST is passed to the memory device 104 by the shared bus RHR logic circuit 112 of the controller 102 transmitting the reset command RST on the shared bidirectional bus 142.

The memory device 104 may include a shared bus RHR logic circuit 122 coupled to the shared bidirectional bus 142. The shared bus RHR logic circuit 122 of the memory device 104 may contain logic to manage the signals transmitted and received by the memory device 102 on the shared bidirectional bus 142. For example, when the memory device 104 is providing the targeted refresh alert RHR_Alert along the shared bidirectional bus 142, the shared bus RHR logic 112 of the controller 102 may transmit a row hammer (RH) mitigation enable RH_M_En signal to the RHR circuit 110 causing the RHR circuit to transmit an RFM command to the memory device 104. If, when the memory device 104 is providing the targeted refresh alert RHR_Alert along the shared bidirectional bus 142, the controller 104 begins providing a reset command RST along the shared bidirectional bus 142, the reset command RST may override the logic of the shared bus RHR logic circuit 122 of the memory device 104. In some embodiments, if the shared bus RHR logic circuit 122 of the memory device 104 receives a command on the shared bidirectional bus 142 that overrides its logic (e.g., a reset command RST), the command is passed to a reset control circuit 124 that may also be included on the memory device 104. The reset control circuit 124 of the memory device 104 manages reset operations of the memory device 104 responsive to the reset command RST.

The memory device 104 may also include a refresh control circuit 120. The refresh control circuit 120 may perform refresh operations. For example, the refresh control circuit 120 may perform targeted refresh operations responsive to RFM commands from the controller 102. In some embodiments, the refresh control circuit 120 may transmit a targeted refresh alert RHR_Alert when the memory device 104 determines that it should perform a targeted refresh operation. The targeted refresh alert RHR_Alert may be transmitted to the shared bus RHR logic circuit 122 of the memory device 104. The shared bus RHR logic circuit 122 of the memory device 104 may subsequently transmit, based on its logic, the targeted refresh alert RHR_Alert to the controller 102 on the shared bidirectional bus 142. Responsive to the targeted refresh alert RHR_Alert, the controller 102 may issue an RFM command to the memory device 104 along the C/A bus 140 coupled to the refresh control circuit 120.

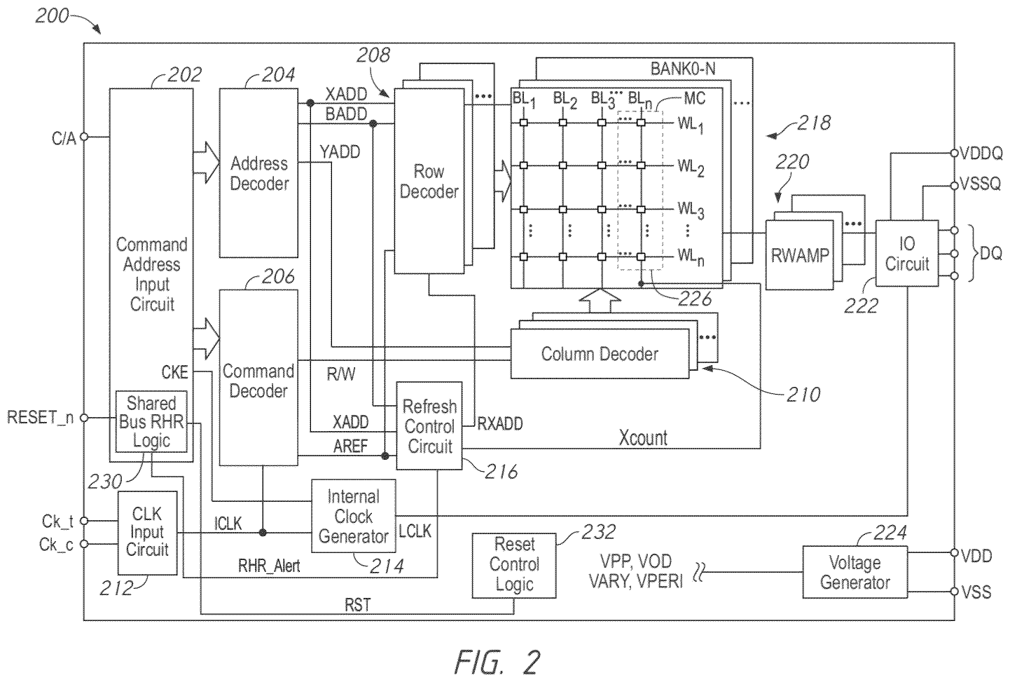

FIG. 2 is a block diagram of a semiconductor device according to at least one embodiment of the disclosure. The semiconductor device 200 may be a semiconductor memory device, such as a DRAM device integrated on a single semiconductor chip. In some embodiments, semiconductor device 200 may be an implementation of memory device 104 in FIG. 1.

The semiconductor device 200 includes a memory array 218. The memory array 218 is shown as including a plurality of memory banks. In the embodiment of FIG. 2, the memory array 218 is shown as including memory banks BANK0-BANKN. The number of memory banks in the memory array 218 may, for example, be 4, 8, 16, or 32. More or fewer banks may be included in the memory array 218 of other embodiments. Each memory bank includes a plurality of word lines WL (rows), a plurality of bit lines BL (columns), and a plurality of memory cells MC arranged at intersections of the plurality of word lines WL and the plurality of bit lines BL.

Some of the memory cells may be set aside as counter memory cells 226. The counter memory cells may store count values XCount, each of which is associated with one of the word lines. Each count value XCount may be stored in counter memory cells 226 along the word line that the count value is associated with. The count value XCount may be stored as a binary number, with each bit stored in a memory cell along the word line. For the sake of clarity, a single bit line of counter memory cells 226 is shown in FIG. 2. However, the number of counter memory cells along each word line may be based on a number of bits of the count value XCount.

The selection of the word line WL is performed by a row decoder 208 and the selection of the bit lines BL is performed by a column decoder 210. In the embodiment of FIG. 2, the row decoder 208 includes a respective row decoder for each memory bank and the column decoder 210 includes a respective column decoder for each memory bank. The bit lines BL are coupled to a respective sense amplifier (not shown). Read data from the bit line BL is amplified by the sense amplifier, and transferred to read/write amplifiers 220 over complementary local data lines (not shown), transfer gate (not shown), and complementary main data lines (not shown). Conversely, write data outputted from the read/write amplifiers 220 is transferred to the sense amplifier over the complementary main data lines, the transfer gate, and the complementary local data lines, and written in the memory cell MC coupled to the bit line BL. Information may generally be read from and written to the counter memory cells 226 in an analogous fashion, except that the data in the counter memory cells 226 are read and written by the refresh control circuit 216.

The semiconductor device 200 may employ a plurality of external terminals that include command and address (C/A) terminals coupled to a command and address bus (e.g., 140 of FIG. 1) to receive commands and addresses, and a CS signal, clock terminals to receive clocks CK and/CK, data terminals DQ to provide data, and power supply terminals to receive power supply potentials VDD, VSS, VDDQ, and VSSQ. In some embodiments, the semiconductor device 200 may include data I/O terminal, or pin, RESET_n to receive commands from, such as a reset command RST, and transmit alerts to, such as a targeted refresh alert RHR_Alert, a controller such as 102 of FIG. 1.

The clock terminals are supplied with external clocks CK and/CK that are provided to an input circuit 212. The external clocks may be complementary. The input circuit 212 generates an internal clock ICLK based on the CK and/CK clocks. The ICLK clock is provided to the command decoder 210 and to an internal clock generator 214. The internal clock generator 214 provides various internal clocks LCLK based on the ICLK clock. The LCLK clocks may be used for timing operation of various internal circuits. The internal data clocks LCLK are provided to the input/output circuit 222 to time operation of circuits included in the input/output (IO) circuit 222, for example, to data receivers to time the receipt of write data.

The C/A terminals may be supplied with memory addresses. The memory addresses supplied to the C/A terminals are transferred, via a command/address input circuit 202, to an address decoder 204. The address decoder 204 receives the address and supplies a decoded row address XADD to the row decoder 208 and supplies a decoded column address YADD to the column decoder 210. The address decoder 204 may also supply a decoded bank address BADD, which may indicate the bank of the memory array 218 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The C/A terminals may be supplied with refresh commands such as the refresh management (RFM) command (e.g., RFM of FIG. 1). The access commands may be associated with one or more row address XADD, column address YADD, and bank address BADD to indicate the memory cell(s) to be accessed.

The commands may be provided as internal command signals to a command decoder 206 via the command/address input circuit 202. The command decoder 206 includes circuits to decode the internal command signals to generate various internal signals and commands for performing operations. For example, the command decoder 206 may provide a row command signal to select a word line and a column command signal to select a bit line.

The semiconductor device 200 may receive an access command which is a row activation command ACT. When the row activation command ACT is received, a bank address BADD and a row address XADD are timely supplied with the row activation command ACT.

The semiconductor device 200 may receive an access command which is a read command. When a read command is received, a bank address BADD and a column address YADD are timely supplied with the read command, read data is read from memory cells in the memory array 218 corresponding to the row address XADD and column address YADD. The read command is received by the command decoder 206, which provides internal commands so that read data from the memory array 218 is provided to the read/write amplifiers 220. The read data is output to outside from the data terminals DQ via the input/output circuit 222. The access count Xcount stored in the counter memory cells 226 of the row associated with the row address XADD is read to the refresh control circuit 216, and an updated value of the access count Xcount′ (not shown) is written back to the counter memory cells 226 of the row XADD.

The semiconductor device 200 may receive an access command which is a write command. When the write command is received, a bank address BADD and a column address YADD are timely supplied with the write command, write data supplied to the data terminals DQ is written to a memory cell in the memory array 218 corresponding to the row address and column address. The write command is received by the command decoder 206, which provides internal commands so that the write data is received by data receivers in the input/output (IO) circuit 222. Write clocks may also be provided to the external clock terminals for timing the receipt of the write data by the data receivers of the input/output circuit 222. The write data is supplied via the input/output circuit 222 to the read/write amplifiers 220, and by the read/write amplifiers 220 to the memory array 218 to be written into the memory cell MC. Similar to the read operation described above, the access count Xcount stored in the counter memory cells 226 of the row associated with the row address XADD is read to the refresh control circuit 216, and an updated value of the access count Xcount′ is written back to the counter memory cells 226 of the row XADD.

The semiconductor device 200 may also receive commands causing it to carry out one or more refresh operations. For example, responsive to a refresh command, the command decoder 206 may provide refresh signals such as REF, RFM or combinations thereof. Responsive to a refresh command received from the controller, the refresh control circuit 216 performs one or more normal refresh operations, one or more targeted refresh operations, or combinations thereof. Responsive to an RFM command received from the controller, the refresh control circuit 216 performs one or more targeted refresh operations.

The refresh signal REF is supplied to the refresh control circuit 216. The refresh control circuit 216 (e.g., 120 of FIG. 1) supplies a refresh row address RXADD to the row decoder 208, which may refresh a word line WL indicated by the refresh row address RXADD. The refresh control circuit 216 may control a timing of the refresh operation, and may generate and provide the refresh address RXADD. The refresh control circuit 216 may be controlled to change details of the refreshing address RXADD (e.g., how the refresh address is calculated, the timing of the refresh addresses), or may operate based on internal logic.

The refresh control circuit 216 may selectively output a targeted refresh address (e.g., a victim address) or a normal refresh address as the refreshing address RXADD. The normal refresh addresses may be a sequence of addresses which are provided based on activations of the refresh signal REF. The refresh control circuit 216 may cycle through the sequence of refresh addresses at a rate determined by REF. In some embodiments, the sequence of refresh addresses may include all the addresses in the memory bank 218. In some embodiments, the refresh signal REF may be issued with a frequency such that most or all of the addresses in the memory bank 218 are refreshed within a certain period, which may be based on an expected rate at which information in the memory cells MC decays.

The refresh control circuit 216 may also determine targeted refresh addresses which are addresses that require refreshing (e.g., victim addresses corresponding to victim rows) based on the access pattern of nearby addresses (e.g., aggressor addresses associated with aggressor rows) in the memory array 218. The refresh control circuit 216 may monitor accesses to the different word lines WL of the memory bank. When the row decoder 208 sends an access command to a particular row, the counter memory cells 226 along that row may have their information read to the refresh control circuit 216 as the access count Xcount. The refresh control circuit 216 may determine an access count of the row based on the values stored in the counter memory cells 226 of the accessed row.

The refresh control circuit 216 may determine if the accessed row is an aggressor row based on the access count from the counter memory cells 226. If the current row is not an aggressor row, the value of the access count may be changed and then the refresh control circuit 216 may write the new value of the access count back to the counter memory cells 226 of the accessed row. If the refresh control circuit 216 determines that the accessed row is an aggressor, then the refresh control circuit 216 may use the row address XADD of the accessed row to determine one or more victim row addresses and provide them as a refresh address RXADD as part of a targeted refresh operation. When the accessed row is determined to be an aggressor, the access count Xcount associated with that row may be reset (e.g., to a minimum value, such as 0). In some embodiments, the refresh control circuit 216 may queue up identified aggressor addresses (e.g., in an aggressor queue) for later use in targeted refresh operations.

The memory device 200 may indicate to the controller that a targeted refresh operation is called for. For example, if the aggressor queue contains over a threshold number of stored addresses. To initiate a targeted refresh operation, the refresh control circuit 216 may issue a targeted refresh alert RHR_Alert to a shared bus RHR logic circuit 230 (e.g., 122 of FIG. 1). Responsive to the targeted refresh alert RHR_Alert, the controller may issue an RFM command, causing the memory 200 to perform one or more targeted refresh operations. In some embodiments, the targeted refresh alert RHR_Alert may be one or more pulses, or a pulse train. For example, the targeted refresh alert RHR_Alert may consist of two pulses. The first pulse may indicate to the controller to begin issuing one or more RFM commands and the second pulse may indicate to the controller to stop issuing RFM commands.

In some embodiments, a shared bus RHR logic circuit 230 may be included in the command address input circuit 202, as shown in FIG. 2. Responsive to receiving the targeted refresh alert RHR_Alert from the refresh control circuit 216, the shared bus RHR logic circuit 230 may transmit a target refresh alert to a controller (e.g., 102 of FIG. 1), for example via a shared bidirectional bus (e.g., 142 of FIG. 1). In some embodiments, the shared bidirectional bus (e.g., 142 of FIG. 1) may be coupled to I/O pin RESET_n. The shared bus RHR logic circuit 230 may also, in some embodiments, receive external command signals such as a reset command RST via the shared bidirectional bus (e.g., 142 of FIG. 1). Responsive to the reset command RST, the shared bus RHR logic circuit 230 will issue a reset command RST to a reset control logic circuit 232 (e.g., 124 of FIG. 1) to perform reset operations on the semiconductor device 200. In some embodiments, the shared bidirectional bus may be connected to other pins or terminals on the memory device and configured to receive other external commands. For example, the shared bidirectional bus may be connected to ZQ of the memory device and be configured to receive calibration commands from the controller (e.g., 102 of FIG. 1).

The power supply terminals are supplied with power supply potentials VDD and VSS. The power supply potentials VDD and VSS are supplied to an internal voltage generator circuit 224. The internal voltage generator circuit 224 generates various internal potentials VPP, VOD, VARY, VPERI, and the like based on the power supply potentials VDD and VSS supplied to the power supply terminals. The internal potential VPP is mainly used in the row decoder 208, the internal potentials VOD and VARY are mainly used in the sense amplifiers included in the memory array 218, and the internal potential VPERI is used in many peripheral circuit blocks. The power supply terminals are also supplied with power supply potentials VDDQ and VSSQ. The power supply potentials VDDQ and VSSQ are supplied to the input/output circuit 222.

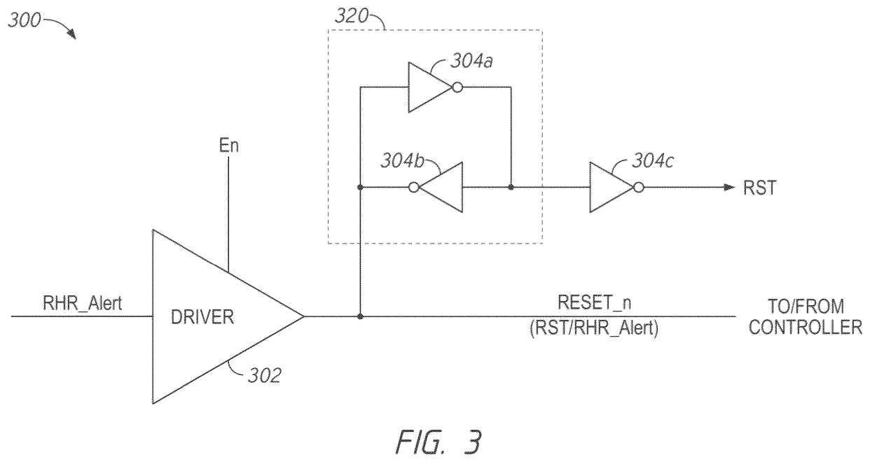

FIG. 3 is a schematic diagram of a shared bus RHR logic circuit that may be included on a memory device according to at least one embodiment of the disclosure. Circuit 300 may be an implementation of the shared bus RHR logic circuit 122 of FIGS. 1 and/or 230 of FIG. 2.

Circuit 300 may be configured to manage the signals transmitted from and received by the memory device (e.g., 104 of FIGS. 1 and/or 200 of FIG. 2) on the shared bidirectional bus RESET_n (e.g., 142 of FIG. 1). In other words, circuit 300 may transmit and receive signals on the shared bidirectional bus (e.g., 142 of FIG. 1). In some embodiments, the signals received may be commands, such as a reset command RST, from a controller (e.g., 102 of FIG. 1) and the signals transmitted may be alerts, such as targeted refresh alerts RHR_ALERT.

Circuit 300 may be configured to allow a memory device (e.g., memory device 104 of FIG. 1 and/or semiconductor device 200 of FIG. 2) to transmit signals on a shared bidirectional bus coupled to a pin or terminal configured to receive external signals. For example, the shared bidirectional bus (e.g., 142 of FIG. 1) may be coupled to a pin or terminal such as RESET_n on the memory device. In some embodiments, the shared bidirectional bus RESET_n (e.g., 142 of FIG. 1) coupled to the RESET_n terminal may be configured to receive a reset command (e.g., RST of FIG. 1) from a controller (e.g., 102 of FIG. 1). In some embodiments, the shared bidirectional bus (e.g., 142 of FIG. 1) may be connected to other pins or terminals on the memory device and configured to receive other external signals. For example, the shared bidirectional bus may be connected to pin ZQ of the memory device and be configured to receive a calibration command from a controller.

The circuit 300 may include a driver 302 coupled to the shared bidirectional bus RESET_n (e.g., 142 of FIG. 1). In some embodiments, the driver 302 may be a tri-state driver. The driver 302 may drive a signal on to the shared bidirectional bus (e.g., 142 of FIG. 1) to be transmitted from the memory device (e.g., 104 of FIGS. 1 and/or 200 of FIG. 2), for example to the controller (e.g., 102 of FIG. 1). In some embodiments, the driver 302 may drive a targeted refresh alert RHR_Alert on to the shared bidirectional bus RESET_n (e.g., 142 of FIG. 1). The targeted refresh alert RHR_Alert may be issued, in some embodiments, by a refresh control circuit (e.g., 120 of FIGS. 1 and/or 216 of FIG. 2). The driver 302 may drive the targeted refresh alert RHR_Alert on to the shared bidirectional bus RESET_n (e.g., 142 of FIG. 1) when enabled by an enable signal En that may be issued by the refresh control circuit (e.g., 120 of FIGS. 1 and/or 216 of FIG. 2) along with the targeted refresh alert RHR_Alert.

The circuit 300 may include a latch 320 coupled to the shared bidirectional bus (e.g., 142 of FIG. 1). Latch 320 may be made up of inverters 304a and 304b and coupled to the output of the driver 302. Latch 320 may be configured such that a command received on the shared bidirectional bus may be able to flip the latch 320 and reach the applicable memory logic causing the memory device (e.g., 104 of FIGS. 1 and/or 200 of FIG. 2) to perform a desired operation. For example, circuit 300 may receive a reset command RST from a controller (e.g., 102 of FIG. 1) on the shared bidirectional bus RESET_n (e.g., 142 of FIG. 1). The reset command RST may be strong enough to flip latch 320 and pass the signal through a third inverter 304c to another component of the semiconductor device (e.g., 104 of FIGS. 1 and/or 200 of FIG. 2), such as the reset control circuit (e.g., 232 of FIG. 2). Responsive to receiving the reset command RST, the reset control logic circuit (e.g., 232 of FIG. 2) causes the memory device (e.g., 104 of FIGS. 1 and/or 200 of FIG. 2) to perform reset operations.

On the other hand, a signal transmitted from the driver 302 may not be strong enough to flip latch 320 and will be transmitted along the shared bidirectional bus RESET_n (e.g., 142 of FIG. 1), for example to the controller (e.g., 102 of FIG. 1). In some embodiments, the signal transmitted may be a targeted refresh alert RHR_Alert and the latch 320 may cause the targeted refresh alert RHR_Alert to be transmitted along the shared bidirectional bus RESET_n (e.g., 142 of FIG. 1). In other words, the targeted refresh alert RHR_Alert may not be able to reach components coupled to the shared bidirectional bus RESET_n (e.g., 142 of FIG. 1) via the latch 320.

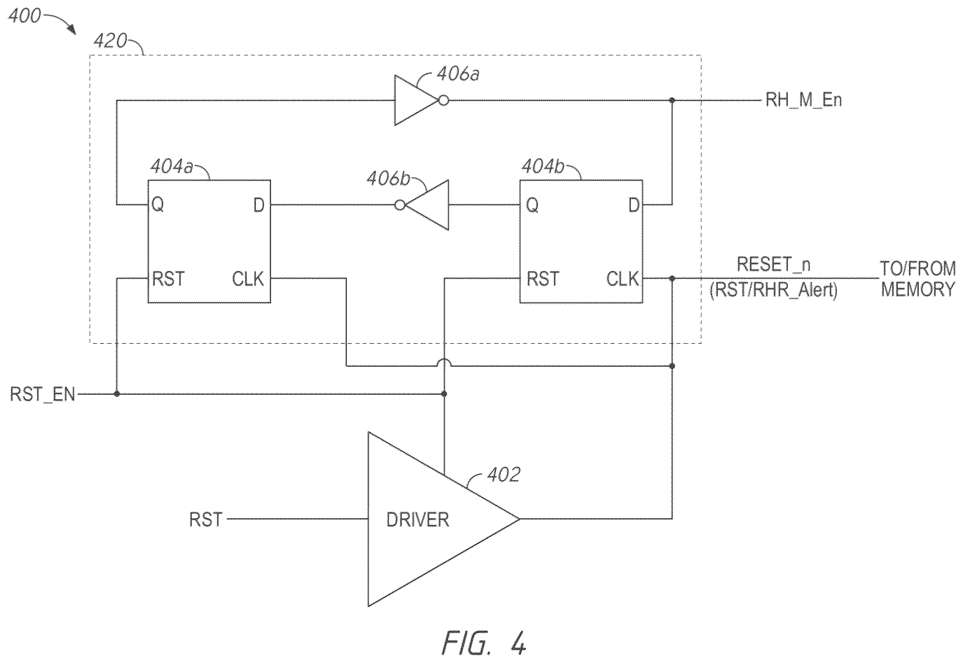

FIG. 4 is a schematic diagram of a shared bus RHR logic circuit that may be included on a controller according to at least one embodiment of the disclosure. Circuit 400 may be an implementation of the shared bus RHR logic circuit 112 of FIG. 1.

Circuit 400 may be configured to allow a controller (e.g., 102 of FIG. 1) to transmit and receive signals on a shared bidirectional bus. For example, the controller (e.g., 102 of FIG. 1) may be configured to transmit a reset command RST to a semiconductor device (e.g., 104 of FIGS. 1 and/or 200 of FIG. 2) on the shared bidirectional bus (e.g., 142 of FIG. 1). In some embodiments, the shared bidirectional bus (e.g., 142 of FIG. 1) may be used by the controller and configured to transmit other commands. For example, the shared bidirectional bus (e.g., 142 of FIG. 1) may be connected to ZQ of the controller and be configured to transmit calibration commands to a semiconductor device (e.g., 104 of FIGS. 1 and/or 200 of FIG. 2).

Circuit 400 may be configured to manage the signals transmitted from and received by the controller (e.g., 102 of FIG. 1) on the shared bidirectional bus RESET_n (e.g., 142 of FIG. 1). For example, responsive to receiving a targeted refresh alert RHR_Alert, circuit 400 may include logic that causes the controller to issue an RFM command to the memory device (e.g., 104 of FIGS. 1 and/or 200 of FIG. 2).

The circuit 400 may include a two-bit counter 420. The two-bit counter 420 may include two latch circuits 404a and 404b. In an example embodiment, clock terminals of the first latch 404b and the second latch 404a coupled to the shared bidirectional bus RESET_n (e.g., 142 of FIG. 1) may receive the targeted refresh alert RHR_Alert. The first latch 404b may have an input terminal coupled to an input of a first inverter 406b. The first inverter 406b may have an output coupled to an input of the second latch 404a. An output of the second latch 404a may be coupled to an input of a second inverter 406a, an output of which may be coupled to an output of the first latch 404b and provide an RH mitigation enable signal RH_M_En to another component, for example a row hammer refresh (RHR) circuit (e.g., 110 of FIG. 1). Accordingly, the latches 404a and 404b may act as a two bit counter where (assuming both latch circuits 404a and 404b start from a reset state) after the targeted refresh alert RHR_Alert is sent, for example as a pulse, from the memory device (e.g., 104 of FIGS. 1 and/or 200 of FIG. 2), the RH mitigation enable signal RH_M_En will remain high until a next targeted refresh alert RHR_Alert is sent, for example as a second pulse, from the memory device (e.g., 104 of FIGS. 1 and/or 200 of FIG. 2). The next targeted refresh alert RHR_Alert is sent by the memory device (e.g., 104 of FIGS. 1 and/or 200 of FIG. 2) to indicate completion of requested targeted refresh. Responsive to a reset enable signal RST_EN from the reset control circuit (e.g., 114 of FIG. 1) of the controller (e.g., 102 of FIG. 1), the two bit counter 420 will be disabled.

The circuit 400 may include a driver 402 coupled to the shared bidirectional bus RESET_n (e.g., 142 of FIG. 1). In some embodiments, the driver 402 may be a tri-state driver. The driver 402 may drive a command on to the shared bidirectional bus (e.g., 142 of FIG. 1) to be transmitted from the controller (e.g., 102 of FIG. 1), for example to the memory device (e.g., 104 of FIGS. 1 and/or 200 of FIG. 2). In some embodiments, the driver 402 may drive a reset command RST on to the shared bidirectional bus RESET_n (e.g., 142 of FIG. 1). The reset command RST may be issued, in some embodiments, by a reset control circuit (e.g., 114 of FIG. 1) of the controller (e.g., 102 of FIG. 1). The driver 402 may drive the reset command RST on to the shared bidirectional bus RESET_n (e.g., 142 of FIG. 1) when enabled by the reset enable signal RST_EN, which may also be issued, in some embodiments, by the reset control circuit (e.g., 114 of FIG. 1) of the controller (e.g., 102 of FIG. 1).

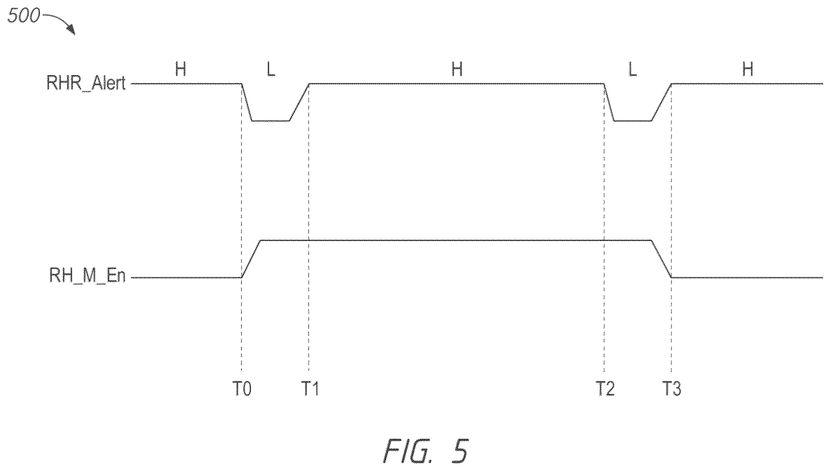

FIG. 5 is a timing diagram of example behaviors of signals according to at least one embodiment of the disclosure. In an example embodiment, the timing diagram 500 may represent the operations of shared bus RHR logic circuits, such as 112 and 122 of FIG. 1, 230 of FIG. 2, 300 of FIG. 3, and/or 400 of FIG. 4. The line RHR_Alert represents the targeted refresh alert RHR_Alert sent along a shared bidirectional bus (e.g., 142 of FIG. 1) by the shared bus RHR logic circuit (e.g., 122 of FIG. 1, 230 of FIG. 2, and/or 300 of FIG. 3) located on the semiconductor device (e.g., 104 of FIGS. 1 and/or 200 of FIG. 2). The line RH_M_En represents the RH mitigation enable signal RH_M_En issued by the shared bus RHR logic circuit (e.g., 112 of FIG. 1) located on the controller (e.g., 102 of FIG. 1) which causes the controller (e.g., 102 of FIG. 1) to issue an RFM command to the memory device (e.g., 104 of FIGS. 1 and/or 200 of FIG. 2) on a C/A bus (e.g., 140 of FIG. 1).

At an initial time T0, the targeted refresh alert RHR_Alert on the shared bidirectional bus (e.g., 142 of FIG. 1 and/or RESET_n of FIGS. 3-4) transitions from a high state to a low state. The targeted refresh alert RHR_Alert may be issued when the semiconductor device (e.g., 104 of FIGS. 1 and/or 200 of FIG. 2) determines that it should perform a targeted refresh operation. Responsive to the targeted refresh alert RHR_Alert, the shared bus RHR logic circuit (e.g., 112 of FIG. 1) located on the controller (e.g., 102 of FIG. 1) issues a RH mitigation enable signal RH_M_En to an RHR logic circuit (e.g., 110 of FIG. 1) on the controller (e.g., 102 of FIG. 1). Also at the initial time T0, the RH mitigation enable signal RH_M_En transitions from a low state to a high state. When the RH mitigation enable signal RH_M_En is in a high state, the controller (e.g., 103 of FIG. 1) issues an RFM command to the memory device (e.g., 104 of FIGS. 1 and/or 200 of FIG. 2).

At time T1, the targeted refresh alert RHR_Alert on the shared bidirectional bus (e.g., 142 of FIG. 1 and/or RESET_n of FIGS. 3-4) transitions back to high. In some embodiments, the targeted refresh alert RHR_Alert may be one or more pulses. The pulses may be any length of time, for example, three nanoseconds. Responsive to the transition of the alert on the shared bidirectional bus (e.g., 142 of FIG. 1 and/or RESET_n of FIGS. 3-4), the RH mitigation enable signal RH_M_En issued from the shared bus RHR logic circuit (e.g., 112 of FIG. 1) of the controller (e.g., 102 of FIG. 1) may not change and may remain in a high state. The RH mitigation enable signal RH_M_En may remain high to indicate to the controller that a targeted refresh operation is occurring and the controller should continue to transmit RFM commands.

At T2, the targeted refresh alert RHR_Alert on the shared bidirectional bus (e.g., 142 of FIG. 1 and/or RESET_n of FIGS. 3-4) may transition from high to low. The targeted refresh alert RHR_Alert may be another pulse. The second pulse may indicate that the memory no longer requires targeted refresh operations. The second pulse ends at a time T3. The second pulse may be any length of time, for example, three nanoseconds. Responsive to the second pulse, the RH mitigation enable signal RH_M_En may transition from high to low at time T3 and the controller will stop transmitting RFM commands.

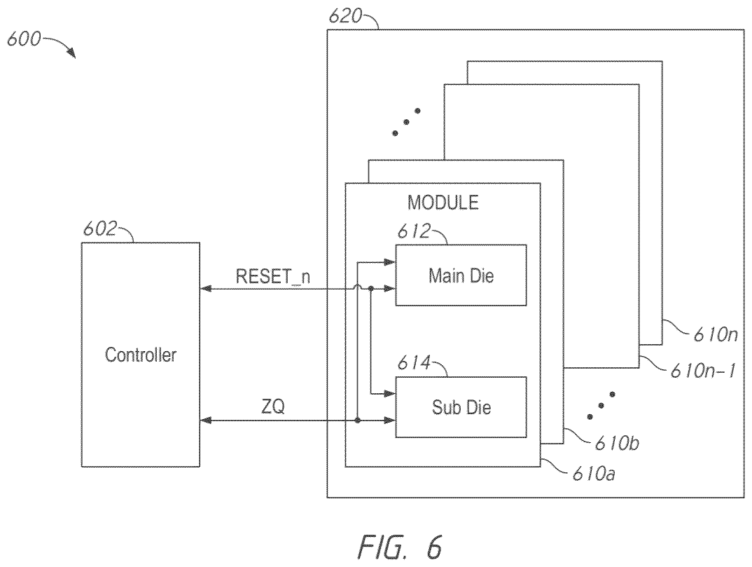

FIG. 6 is a block diagram of a system according to at least one embodiment of the disclosure. System 600 may be an example implementation of system 100 of FIG. 1. For example, the controller 602 may be an implementation of controller 102 of FIG. 1. Main die 612 and sub die 614 may be implementations of memory device 104 of FIG. 1 and/or the semiconductor device 200 of FIG. 2.

The system 600 may include a memory module 620. The memory module 620 may include one or more pairs of memory dies 610a-610n. In the embodiment of FIG. 6, the system 600 is shown as including four pairs 610a-610n. The number of pairs may be any number, for example, be 4, 8, 16, or 32. More or fewer pairs may be included in the system 600 of other embodiments. Each pair 610a-610n may include a pair of memory dies, for example a main die 612 and a sub die 614. In an example embodiment, system 600 may have sixteen pairs 610, each containing two memory dies 612 and 614, for a total of thirty-two memory dies.

The memory dies 612 and 614 may be coupled to the controller 602 with a plurality of buses. For example, command/address buses (not shown in FIG. 6), data buses (not shown), and/or clock buses (not shown). Each of the buses may include one or more signal lines on which signals are provided. The controller 602 (e.g., 102 of FIG. 1) may transmit commands to the pairs 610a-610n and responsive to the transmitted commands, the memory dies 612 and 614 may perform operations. The controller 602 (e.g., 102 of FIG. 1) may be coupled with the pairs 610a-610n with buses to transmit other types of signals, for example a reset bus or a calibration bus to carry reset command or calibration commands, respectively. In some embodiments, the controller 602 (e.g., 102 of FIG. 1) may use a reset bus RESET_n to transmit a reset command RST to the pairs 610a-610n and a calibration bus ZQ to transmit a calibration command to the pairs 610a-610n. Responsive to receiving the signals, the memory dies 612 and 614 may perform reset and calibration operations. The reset bus RESET_n and the calibration bus ZQ may be each coupled to both memory dies of a pair. For example, the reset bus RESET_n may be coupled to both the main die 612 and the sub die 614 and transmit the same reset command to both dies 612 and 614 at the same time. The calibration bus ZQ may also be coupled to both the main die 612 and the sub die 614 and transmit the same calibration command to both dies 612 and 614 at the same time. The memory module 620 may be coupled to the controller 602 (e.g., 102 of FIG. 1) with a command/address bus (not shown) that transmits commands for operations to be performed by the memory dies. The commands may be directed to individual dies, such as targeted refresh commands.

According to some embodiments, the reset bus RESET_n and the calibration bus ZQ may be implementations of the shared bidirectional bus 142 of FIG. 1 and/or RESET_n of FIGS. 3-4 and the memory dies 612 and 614 may use them to transmit signals to controller 602 (e.g., 102 of FIG. 1). For example, the memory dies 612 and 614 may use the buses to transmit targeted refresh alerts to the controller to indicate that the memory dies 612 and 614 determined that they should perform targeted refresh operations.

Because both memory dies 612 and 614 may be connected to both shared bidirectional buses RESET_n and ZQ, the shared bus RHR logic circuit (e.g., 112 of FIG. 1) of the controller 602 (e.g., 102 of FIG. 1) may assign different shared bidirectional buses to each memory die 612 and 614. For example, the shared bus RHR logic circuit (e.g., 112 of FIG. 1) of the controller 602 (e.g., 102 of FIG. 1) may contain logic such that when a targeted refresh alert RHR_Alert is received on a particular shared bidirectional bus, the RFM command for the targeted refresh operation will go to a particular memory die assigned to the shared bidirectional bus. In some embodiments, the reset bus RESET_n may be assigned to the main die 612 and the calibration bus ZQ may be assigned to the sub die 614. Thus, if the shared bus RHR logic circuit (e.g., 112 of FIG. 1) of the controller 602 (e.g., 102 of FIG. 1) receives a targeted refresh alert RHR_Alert on the reset bus RESET_n, an RFM command will be transmitted to the main die 612. However, if the shared bus RHR logic circuit (e.g., 112 of FIG. 1) of the controller 602 (e.g., 102 of FIG. 1) receives a targeted refresh alert RHR_Alert on the calibration bus ZQ, an RFM command will be transmitted to the sub die 614. Determining when each die is to receive the RFM command and in what order, may be accomplished by an arbiter circuit such as is described herein.

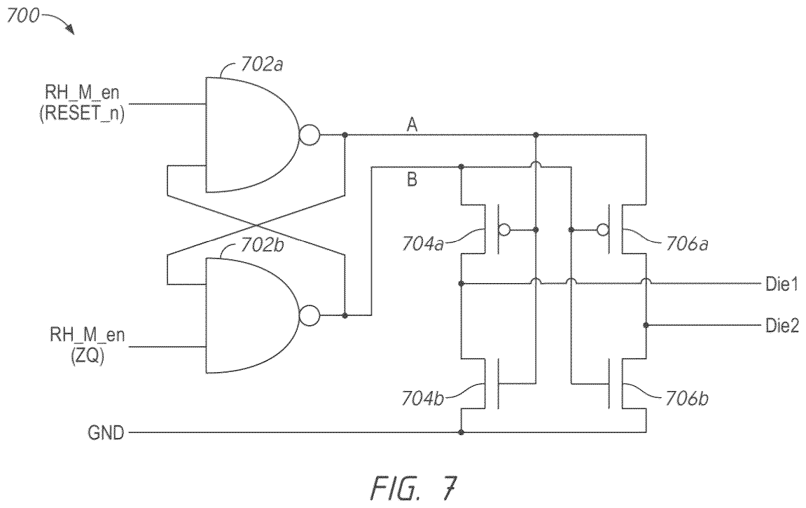

FIG. 7 is a block diagram of an arbiter circuit according to some embodiments of the present disclosure. The arbiter circuit 700 may, in some embodiments, be included in the shared bus RHR logic circuit (e.g., 112 of FIG. 1) located on the controller (e.g., 102 of FIGS. 1 and/or 602 of FIG. 6). The arbiter circuit 700 may be used by the controller (e.g., 102 of FIG. 1 and/or 602 of FIG. 6) to decide which memory die (e.g., main die 612 and/or sub die 614 of FIG. 6) sent a targeted refresh alert RHR_Alert based on which shared bidirectional bus (e.g., RESET_n and/or ZQ) carried the alert in the event that multiple memory dies transmit a targeted refresh alert during overlapping time periods.

For example, each memory die may send a targeted refresh alert RHR_Alert to a controller (e.g., 102 of FIGS. 1 and/or 602 of FIG. 6). A first targeted refresh alert RHR_Alert may be transmitted on a first shared bidirectional bus, such as reset bus RESET_n, to indicate a targeted refresh operation is required for a first memory die Die1, such as main die 612 of FIG. 6. A second targeted refresh alert RHR_Alert may be transmitted on a second shared bidirectional bus, such as calibration bus ZQ, to indicate a targeted refresh operation is required for a second memory die Die2, such as sub die 614 of FIG. 6. Responsive to the targeted refresh alerts, the shared bus logic circuit (e.g., 112 of FIGS. 1 and/or 400 of FIG. 4) of the controller coupled to each shared bidirectional bus RESET_n and ZQ may issue an RH mitigation enable signal RH_M_En for each memory die 612 and 614. The arbiter 700 takes as inputs the multiple RH mitigation enable signals RH_M_En sent from the shared bus logic circuits (e.g., 112 of FIGS. 1 and/or 400 of FIG. 4), one of which is coupled to the shared bidirectional bus RESET_n and one of which is coupled to the shared bidirectional bus ZQ.

The first and second RH mitigation enable signals are first inputs to NAND gates 702a and 702b, respectively. FIG. 7 depicts the RH mitigation enable signal associated with the main memory die (e.g., 612 of FIG. 6) as RH_M_En (RESET_n) because the main memory die is associated with a targeted refresh alert transmitted on the bidirectional bus that also transmits a reset command RST. FIG. 7 depicts the RH mitigation enable signal associated with the sub memory die (e.g., 614 of FIG. 6) as RH_M_En (ZQ) because the sub memory die is associated with a targeted refresh alert transmitted on the bidirectional bus that also transmits a calibration command ZQ. The second input of each NAND gate 702a and 702b is coupled to the output of the other NAND gate. For example, the second input of first NAND gate 702a is coupled to the output of second NAND gate 702b (e.g., second interim signal B) and the second input of the second NAND gate 702b is coupled to the output of the first NAND gate 702a (e.g., first interim signal A). The interim signals A and B are passed to a set of two p-type transistors 704a and 706a and two n-type transistors 704b and 706b. The source of p-type 706a receives first interim signal A and the source of p-type transistor 704a receives the second interim signal B. The drains of the two p-type transistors are coupled to the respective drains of n-type transistors 704b and 706b. The drain signal of p-type transistor 704a and n-type transistor 704b is associated with the first memory die Die1 (e.g., main die 612 of FIG. 6) and output to logic that manages the transmission of an RFM command to the first memory die Die1 (e.g., main die 612 of FIG. 6). The drain signal of p-type transistor 706a and n-type transistor 706b is associated with the second memory die Die2 (e.g., sub die 614 of FIG. 6) and output to logic that manages the transmission of an RFM command to the second memory die Die2 (e.g., sub die 614 of FIG. 6). The sources of n-type transistors 704b and 706b are coupled to ground. The gates of p-type transistor 704a and n-type transistor 704b are coupled to the first interim signal A and the gates of p-type transistor 706a and n-type transistor 706b are coupled to the second interim signal B.

Accordingly, arbiter circuit 700 associates the first memory die Die1 (e.g., main die 612 of FIG. 6) with a targeted refresh alert RHR_Alert transmitted on a first shared bidirectional bus (e.g., RESET_n) and the arbiter circuit 700 associates the second memory die Die2 (e.g., sub die 614 of FIG. 6) with a targeted refresh alert RHR_Alert transmitted on a second shared bidirectional bus (e.g., ZQ). If both memory dies Die1 and Die2 (e.g., main die 612 and sub die 614 of FIG. 6) send a targeted refresh alert RHR_Alert, the arbiter circuit 700 transmits the signals associated with the die from which the arbiter receives the targeted refresh alert RHR_Alert first and transmits the targeted refresh alert RHR_Alert that was received second at a later time after the targeted refresh operations of the first die are complete.

In an example embodiment, when the first memory die Die1 (e.g., main die 612 of FIG. 6) sends a targeted refresh alert RHR_Alert to the controller (e.g., 102 of FIGS. 1 and/or 602 of FIG. 6), a logical high is received at the first input of the first NAND gate 702a from the shared bus logic circuit (e.g., 112 of FIGS. 1 and/or 400 of FIG. 4) of the controller. If the signal on a second shared bidirectional bus ZQ remains low, the high signal associated with the first memory die Die1 is passed as a low interim signal A to the gates of transistors 704a and 704b, activating p-type transistor 704a and passing the logical high signal from the second NAND gate output (interim signal B) to indicate a targeted refresh alert RHR_Alert from the first memory die Die1 (e.g., main die 612 of FIG. 6). The signals would pass in an opposite manner if a high signal is read at the first input of the second NAND gate 702b from the shared bus logic circuit (e.g., 112 of FIGS. 1 and/or 400 of FIG. 4) coupled to the shared bidirectional bus ZQ and the targeted refresh alert RHR_Alert would be associated with the second memory die Die2 (e.g., sub die 614 of FIG. 6). If both NAND gates 702a and 702b receive a high signal, in other words if both memory dies Die1 and Die2 (e.g., main die 612 and sub die 614 of FIG. 6) send a targeted refresh alert RHR_Alert, the arbiter circuit 700 transmits the signals associated with the die from which the arbiter receives the targeted refresh alert RHR_Alert first and transmits the targeted refresh alert RHR_Alert that was received second at a later time after the targeted refresh operations of the first die are complete.

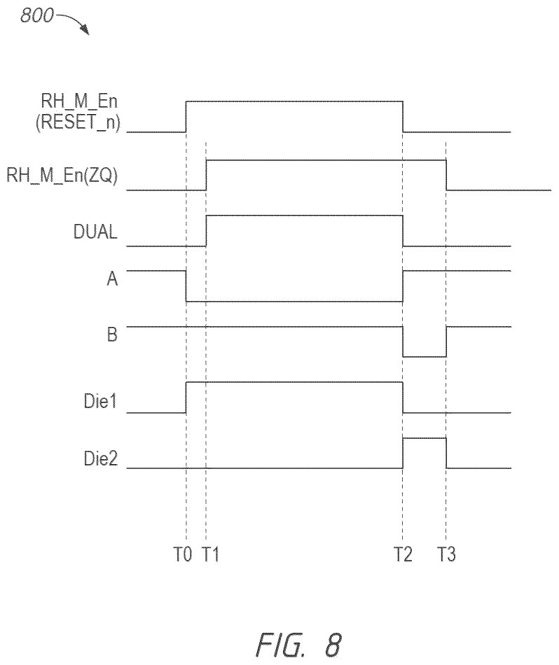

FIG. 8 is a timing diagram of example behaviors of signals according to at least one embodiment of the disclosure. The timing diagram 800 may, in some embodiments, represent the operations of an arbiter circuit, such as 700 of FIG. 7.

According to an example embodiment, the line RH_M_En (RESET_n) may represent the signal issued from a first shared bus logic circuit (e.g., 112 of FIGS. 1 and/or 400 of FIG. 4) of a controller (e.g., 102 of FIG. 1) sent responsive to a first targeted refresh alert RHR_ALERT (RESET_n) transmitted on a first shared bidirectional bus (e.g., RESET_n of FIG. 6) by a first memory die (e.g., main die 612 of FIG. 6). The line RH_M_En (ZQ) may represent the signal issued from a second shared bus logic circuit (e.g., 112 of FIGS. 1 and/or 400 of FIG. 4) of a controller (e.g., 102 of FIG. 1) sent responsive to a second targeted refresh alert RHR_ALERT (ZQ) transmitted on a second shared bidirectional bus (e.g., ZQ of FIG. 6) by a second memory die Die2 (e.g., sub die 614 of FIG. 6). The line DUAL may depict a signal representing when both shared bidirectional buses RESET_n and ZQ are transmitting a targeted refresh alert RHR_Alert. Signal DUAL may be generated by passing the signals on both of the shared bus logic circuits RH_M_En (RESET_n) and RH_M_En (ZQ) through an AND logic gate. Lines A and B may represent interim signals A and B of FIG. 7. Lines Die1 and Die2 may correspond to outputs associated with the first and second memory dies Die1 (e.g., main die 612 of FIG. 6) and Die2 (e.g., sub die 614 of FIG. 6) of an arbiter circuit, such as arbiter circuit 700 of FIG. 7. For example, the output signal Die1 (e.g., main die 612 of FIG. 6) may correspond to the targeted refresh alert RHR_ALERT signal transmitted on the shared bidirectional bus RESET_n and the output signal Die2 (e.g., sub die 614 of FIG. 6) may correspond to the targeted refresh alert RHR_ALERT signal transmitted on the shared bidirectional bus ZQ.

At an initial time TO, a first RH mitigation enable signal RH_M_En (RESET_n) may transition, for example from low to high, responsive to a first targeted refresh alert RHR_ALERT (RESET_n) transmitted on a first shared bidirectional bus RESET_n. The first targeted refresh alert RHR_Alert (RESET_n) may be transmitted from a first memory die, such as main die 612 of FIG. 6, to indicate to the controller (e.g., 102 of FIGS. 1 and/or 602 of FIG. 6) that the first memory die (e.g., main die 612 of FIG. 6) determined that it should perform targeted refresh operations. The first targeted refresh alert RHR_ALERT (RESET_n) may be a first pulse. Also at the time TO, a first interim signal A (e.g., interim signal A of FIG. 7) may transition low and an output signal Die1 (e.g., output signal Die1 of FIG. 7) may transition, for example from low to high.

A time later, at time T1, a second RH mitigation enable signal RH_M_En (ZQ) may transition, for example from low to high, responsive to a second targeted refresh alert RHR_ALERT (ZQ) transmitted on a second shared bidirectional bus ZQ. The second targeted refresh alert may be from a second memory die, such as sub die 614 of FIG. 6. For the time when both RH mitigation enable signals RH_M_En (RESET_n) and RH_M_En (ZQ) are high, a signal representing this overlap, DUAL, may also go high. For example, the signal DUAL transitions to high at T1, the time when both targeted refresh alerts RHR_ALERT (RESET_n) and RHR_Alert (ZQ) are high. The signal DUAL may, in some embodiments, be an input to a refresh management logic circuit, such as is described herein, that manages when an RFM command is sent to which memory die when both memory dies transmit a targeted refresh alert during an overlapping time period.

At a next time T2, the first RH mitigation enable signal RH_M_En (RESET_n) may transition again, for example from high to low, responsive to the first targeted refresh alert RHR_ALERT (RESET_n) transmitted on the first shared bidirectional bus RESET_n. The first targeted refresh alert RHR_ALERTS (RESET_n) may be a second pulse to indicate that the targeted refresh operations are complete on the first memory die (e.g., main die 612 of FIG. 6). Also at the time T2, the interim signal A (e.g., interim signal A of FIG. 7) may transition, for example, interim signal A (e.g., A of FIG. 7) may transition high responsive to the first RH mitigation signal RH_M_En (RESET_n) transitioning low. Also responsive to the first RH mitigation signal RH_M_En (RESET_n) transitioning, an output Die1 associated with the first memory die may transition. For example, at the time T2, responsive to the first RH mitigation signal RH_M_En (RESET_n) transitioning low, the output signal Die1 (e.g., Die1 of FIG. 7) may transition low to indicate to the controller (e.g., 102 of FIGS. 1 and/or 602 of FIG. 6) to stop transmitting RFM commands to the first memory die (e.g., main die 612 of FIG. 6).

Additionally, the signal DUAL will transition at time T2 because the first RH mitigation signal RH_M_En (RESET_n) is no longer in the same active, or high, state as the second RH mitigation signal RH_M_En (ZQ). Responsive to this change, at time T2, the interim signal B (e.g., interim signal B of FIG. 7) associated with the second RH mitigation signal RH_M_En (ZQ) may transition after being delayed by the controller (e.g., 102 of FIGS. 1 and/or 602 of FIG. 6), such as by the arbiter circuit 700. For example, interim signal B (e.g., B of FIG. 7) may transition low responsive to the second RH mitigation signal RH_M_En (ZQ) transitioning high and an output signal Die2 (e.g., output signal Die2 of FIG. 7) may transition. Responsive to the first RH mitigation signal RH_M_En (RESET_n) transitioning low, or going inactive, and the second RH mitigation signal RH_M_En (ZQ) remaining high, or active, the output signal Die2 may transition high to indicate to the controller (e.g., 102 of FIGS. 1 and/or 602 of FIG. 6) to transmit RFM commands to the second memory die (e.g., sub die 614 of FIG. 6).

At a next time T3, the second RH mitigation signal RH_M_En (ZQ) may transition again, for example from high to low, responsive to a second pulse of the second targeted refresh alert RHR_ALERT (ZQ) to indicate that targeted refresh operations are complete on the second memory die (e.g., sub die 614 of FIG. 6). Also at the time T3, the interim signal B (e.g., interim signal B of FIG. 7) may transition, for example, from low to high responsive to the second RH mitigation signal RH_M_En (ZQ) transitioning low. Also responsive to the second RH mitigation signal RH_M_En (ZQ) transitioning, an output signal Die2 associated with the second memory die (e.g., sub die 614 of FIG. 6) may transition. For example, at the time T3, responsive to the second RH mitigation signal RH_M_En (ZQ) transitioning low, or inactive, the output signal Die2 may transition low to indicate to the controller (e.g., 102 of FIGS. 1 and/or 602 of FIG. 6) to stop transmitting RFM commands to the second memory die (e.g., sub die 614 of FIG. 6).

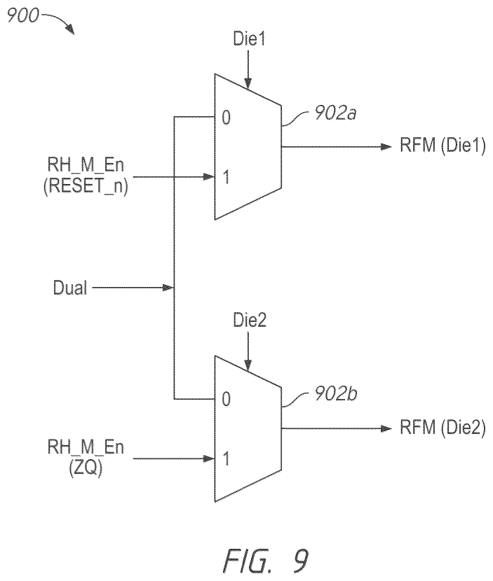

FIG. 9 is a block diagram of a refresh management (RFM) logic circuit according to some embodiments of the present disclosure. The RFM logic circuit 900 may, in some embodiments, be included in the RHR circuit (e.g., 110 of FIG. 1) located on the controller (e.g., 102 of FIGS. 1 and/or 602 of FIG. 6). The RFM logic circuit 900 may be used by the controller to decide which memory die to send an RFM command to based on which memory die sent a targeted refresh alert RHR_Alert as determined by an arbiter circuit, such as arbiter circuit 700 of FIG. 7. For example, there may be an RFM logic circuit 900 for each pair of memory dies (e.g., 612/614 of FIG. 6) on the memory module (e.g., 620 of FIG. 6).

The RFM logic circuit 900 may include a plurality of multiplexers each associated with a memory die. For example, the RFM logic circuit 900 may include two multiplexers 902a and 902b. The first multiplexer 902a may be associated with a first memory die Die1 (e.g., main die 612 of FIG. 6) and the second multiplexer 902b may be associated with a second memory die Die2 (e.g., sub die 614 of FIG. 6). The multiplexers 902a and 902b may manage the transmission of RFM commands to the memory dies based on which memory die transmitted a targeted refresh alert RHR_Alert and the output signals from the arbiter circuit (e.g., 700 of FIG. 7).

In an example embodiment, a first multiplexer 902a associated with a first memory die Die1 (e.g., main die 612 of FIG. 6) receives as inputs a first RH mitigation signal RH_M_En (RESET_n) responsive to a first targeted refresh alert RHR_Alert (RESET_n) associated with the first memory die Die1 (e.g., main die 612 of FIG. 6) and a signal Dual that represents when multiple memory dies are transmitting a targeted refresh alert during the same time period. As a select signal, the first multiplexer 902a receives the output signal Die1 of the arbiter circuit (e.g., 700 of FIG. 7) associated with the first memory die (e.g., main die 612 of FIG. 6). Similarly, a second multiplexer 902b associated with a second memory die (e.g., sub die 614 of FIG. 6) receives as inputs a second RH mitigation signal RH_M_En (ZQ) responsive to a second targeted refresh alert RHR_Alert (ZQ) associated with the second memory die Die2 and the signal Dual. As a select signal, the second multiplexer 902b receives the output signal of the arbiter circuit (e.g., 700 of FIG. 7) associated with the second memory die Die2.

When the first targeted refresh alert RHR_Alert (RESET_n) is transmitted on a first shared bidirectional bus RESET_n and there is no second targeted refresh alert RHR_Alert (ZQ) being transmitted on a second shared bidirectional bus ZQ, the first output Die1 of the arbiter circuit (e.g., 700 of FIG. 7) will be high and the signal Dual will be low. Thus, the output of the first multiplexer 902a will result in an RFM command RFM (Die1) being transmitted in a high state to the first memory die (e.g., main die 612 of FIG. 6). If while the first targeted refresh alert RHR_alert (RESET_n) is being transmitted, the second targeted refresh alert RHR_Alert (ZQ) is transmitted on the second shared bidirectional bus ZQ, the signal Dual will transition to high but the output Die2 of the arbiter circuit (e.g., 700 of FIG. 7) associated with the second targeted refresh alert RHR_Alert (ZQ) will remain low. Thus, the output of the second multiplexer 902b will result in an RFM command RFM (Die2) being transmitted to the first memory die (e.g., main die 612 of FIG. 6).

When the first memory die (e.g., main die 612 of FIG. 6) stops transmitting the first targeted refresh alert RHR_Alert (RESET_n), both the signal Dual and the output Die1 of the arbiter circuit (e.g., 700 of FIG. 7) associated with the first memory die (e.g., main die 612 of FIG. 6) will transition to low. The first multiplexer 902a will transition the RFM (Die1) signal in a low state indicating to stop transmitting the RFM command to the first memory die (e.g., main die 612 of FIG. 6). Also when the first memory die (e.g., main die 612 of FIG. 6) stops transmitting the first targeted refresh alert RHR_Alert (RESET_n), the output Die 2 of the arbiter circuit (e.g., 700 of FIG. 7) associated with the second memory die (e.g., sub die 614 of FIG. 6) will transition to high. Thus, the second multiplexer 902b will continue to transmit the RFM command RFM (Die2) in a high state to the to the second memory die (e.g., sub die 614 of FIG. 6).

When the second memory die (e.g., sub die 614 of FIG. 6) stops transmitting the second targeted refresh alert RHR_Alert (ZQ), the output Die 2 of the arbiter circuit (e.g., 700 of FIG. 7) will transition to and the output of the second multiplexer 902b will transition the RFM (Die2) signal to a low state indicating to stop transmitting the RFM command to the second memory die (e.g., sub die 614 of FIG. 6).

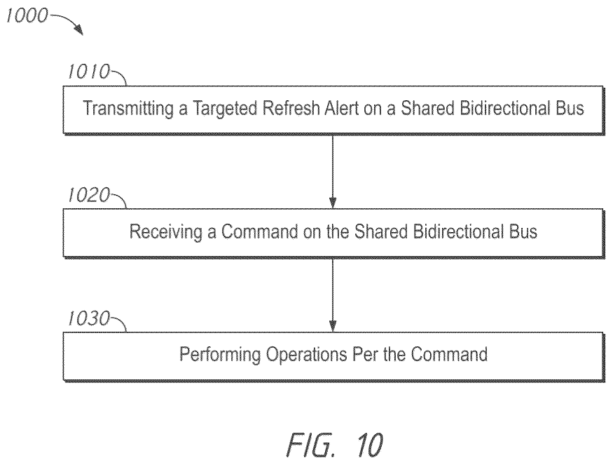

FIG. 10 is a flow chart of a method according to some embodiments of the present disclosure. The method 1000 may, in some embodiments, be implemented by one or more of the apparatuses or systems described herein. For example, the method 1000 may be implemented by the memory device 104 of FIG. 1 and/or the semiconductor device 200 of FIG. 2.

The method 1000 may generally begin with box 1010, which describes transmitting a targeted refresh alert on a shared bidirectional bus. The targeted refresh alert may be the targeted refresh alert RHR_Alert of FIGS. 1-9. The shared bidirectional bus may be an implementation of shared bidirectional bus 142 of FIG. 1, RESET_n of FIGS. 3, 4, 6, and/or ZQ of FIG. 6. For example, the method 1000 may be implemented by a first memory die (e.g., main die 612 of FIG. 6) that transmits a targeted refresh alert RHR_Alert to a controller (e.g., 102 of FIGS. 1 and/or 602 of FIG. 6) on a shared bidirectional bus RESET_n (e.g., 142 of FIG. 1) to indicate that the memory device has determined that it should perform targeted refresh operations and, thus the request for an RFM command to be issued by the controller (e.g., 102 of FIGS. 1 and/or 602 of FIG. 6) to the first memory device (e.g., main die 612 of FIG. 6). Once the targeted refresh alert is transmitted, the method 1000 may proceed to box 1020.

Box 1020 describes receiving a command on the shared bidirectional bus. The command may be transmitted by a controller (e.g., 102 of FIGS. 1 and/or 602 of FIG. 6) to a memory device (e.g., 104 of FIG. 1, 200 of FIG. 2, and/or 612/614 of FIG. 6). The command may, in some embodiments, be a reset command (e.g., RST of FIGS. 1, 3, 4) or a calibration command. The shared bidirectional bus may be an implementation of shared bidirectional bus 142 of FIG. 1, RESET_n of FIGS. 3, 4, 6, and/or ZQ of FIG. 6. Once the command is received, the method 1000 may proceed to box 1030.

Box 1030 describes performing operations per the command. The command may be an external command, such as a reset command or a calibrate command, from a controller (e.g., 102 of FIGS. 1 and/or 602 of FIG. 6) to a memory device (e.g., the memory device 104 of FIG. 1, the semiconductor device 200 of FIG. 2, and/or the memory die 612/614 of FIG. 6). For example, the first memory die (e.g., main die 612 of FIG. 6) may receive an external reset command RST from the controller (e.g., 102 of FIGS. 1 and/or 602 of FIG. 6) to perform reset operations on the shared command bus RESET_n. Responsive to the reset command (e.g., RST of FIGS. 1, 3, 4), the first memory die (e.g., main die 612 of FIG. 6 may perform a reset operation.

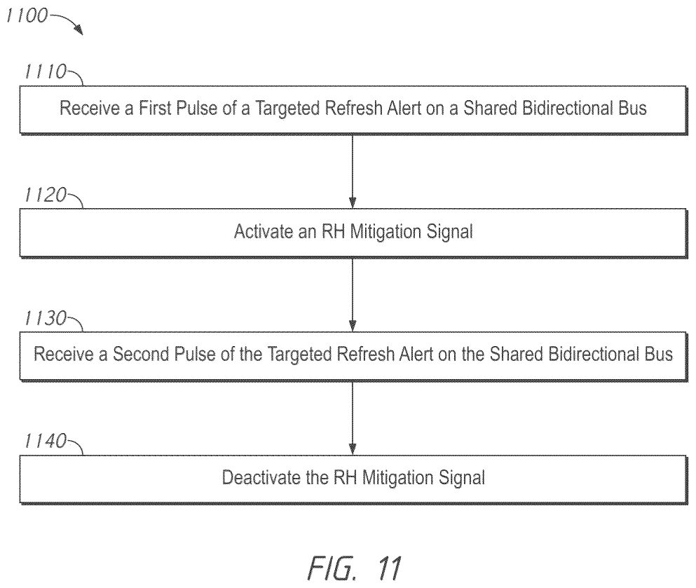

FIG. 11 is a flow chart of a method according to some embodiments of the present disclosure. The method 1100 may, in some embodiments, be implemented by one or more of the apparatuses or systems described herein. For example, the method 1100 may be implemented by the controller 102 of FIGS. 1 and/or 602 of FIG. 6.

The method 1100 may generally begin with box 1110, which describes receiving a first pulse of a targeted refresh alert on a shared bidirectional bus. The targeted refresh alert may be the targeted refresh alert RHR_ALERT (e.g., RHR_ALERT of FIGS. 1-9) transmitted by a memory device (e.g., the memory device 104 of FIG. 1, the semiconductor device 200 of FIG. 2, and/or the memory die 612/614 of FIG. 6). The shared bidirectional bus may be an implementation of shared bidirectional bus 142 of FIG. 1, RESET_n of FIGS. 3, 4, 6, and/or ZQ of FIG. 6. The targeted refresh alert RHR_ALERT may include one or more pulses. The first pulse of the targeted refresh alert may be the first pulse transmitted of a series of one or more pulses. The first pulse may be transmitted when the memory device (e.g., the memory device 104 of FIG. 1, the semiconductor device 200 of FIG. 2, and/or the memory die 612/614 of FIG. 6) determines that it should perform a targeted refresh operation. Responsive to receiving the first pulse of the targeted refresh alert, the method 1100 may proceed to box 1120.

Box 1120 describes activating an RH mitigation signal. The RH mitigation signal may be an RH mitigation enable signal such as RH_M_En of FIGS. 1, 4-5, and 7-9. The RH mitigation signal may be activated responsive to receiving the targeted refresh alert at, for example, a shared bus logic circuit (e.g., 112 of FIG. 1) of the controller (e.g., 102 of FIGS. 1 and/or 602 of FIG. 6). Responsive to the activated RH mitigation signal, the controller (e.g., 102 of FIGS. 1 and/or 602 of FIG. 6) may transmit an RFM command to the memory device (e.g., the memory device 104 of FIG. 1, the semiconductor device 200 of FIG. 2, and/or the memory die 612/614 of FIG. 6). After activating the RH mitigation signal, the method 1100 may proceed to box 1130. Box 1130 describes receiving a second pulse of the targeted refresh alert on the shared bidirectional bus. The second pulse of the targeted refresh alert may be transmitted when the memory device (e.g., the memory device 104 of FIG. 1, the semiconductor device 200 of FIG. 2, and/or the memory die 612/614 of FIG. 6) determines that the performance of the targeted refresh operation is complete. Responsive to receiving the second pulse of the targeted refresh alert, the method 1100 may proceed to box 1140.

Box 1140 describes deactivating the RH mitigation signal. The RH mitigation signal may be deactivated responsive to receiving the targeted refresh alert at, for example, a shared bus logic circuit (e.g., 112 of FIG. 1) of the controller (e.g., 102 of FIGS. 1 and/or 602 of FIG. 6). Responsive to the deactivated RH mitigation signal, the controller (e.g., 102 of FIGS. 1 and/or 602 of FIG. 6) may stop transmitting the RFM commands to the memory device (e.g., the memory device 104 of FIG. 1, the semiconductor device 200 of FIG. 2, and/or the memory die 612/614 of FIG. 6).

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. A system comprising:
a controller;
a memory; and
a shared bidirectional bus, wherein the shared bidirectional bus is coupled between the controller and the memory and wherein the controller is configured to transmit a command on the shared bidirectional bus and the memory is configured to transmit a targeted refresh alert on the shared bidirectional bus.

2. The system of claim 1, wherein the command is a reset command.

3. The system of claim 1, wherein the controller is further configured to issue a refresh management (RFM) command to the memory responsive to the targeted refresh alert.

4. The system of claim 3, further comprising a command/address bus coupled between the controller and the memory and wherein the RFM command is transmitted on the command/address bus.

5. The system of claim 1, further comprising:
a second memory; and
a second shared bidirectional bus coupled between the controller and the second memory, wherein the controller is configured to transmit a second command on the second shared bidirectional bus and the second memory is configured to transmit a second targeted refresh alert on the second shared bidirectional bus and wherein the controller is further configured to transmit a refresh command to the second memory responsive to receiving the second targeted refresh alert on the second shared bidirectional bus.

6. The system of claim 5, wherein the memory is coupled to the second shared bidirectional bus and the second memory is coupled to the shared bidirectional bus and wherein the second command is a calibration command and the command and the second command are received by the memory and the second memory.

7. An apparatus comprising:
a shared bus logic circuit configured to receive a command and to transmit a targeted refresh alert on a shared bidirectional bus; and
a refresh control circuit coupled to the shared bus logic circuit, wherein the refresh control circuit is configured to perform a refresh operation and to cause the shared bus logic circuit to transmit the targeted refresh alert.

8. The apparatus of claim 7, further comprising a reset control circuit coupled to the refresh control circuit and configured to perform a reset operation responsive to the command and wherein the command is a reset command.

9. The apparatus of claim 7, further comprising a command/address bus coupled between a controller and the refresh control circuit, wherein the controller is configured to transmit a refresh command responsive to receiving the targeted refresh alert and wherein the refresh control circuit is further configured to perform targeted refresh operations responsive to receiving the refresh command.

10. The apparatus of claim 7, wherein the command overrides the targeted refresh alert when the command and the targeted refresh alert are transmitted during overlapping time periods.

11. The apparatus of claim 7, wherein the shared bus logic circuit further comprises:
a driver; and
a latch, wherein the shared bidirectional bus is coupled to an output of the driver and an input of the latch.

12. The apparatus of claim 11, wherein the driver is a tri-state driver.

13. The apparatus of claim 11, wherein the driver is configured to receive the targeted refresh alert and an enable signal from the refresh control circuit and further configured to transmit the targeted refresh alert on the shared bidirectional bus responsive to the enable signal.

14. The apparatus of claim 11, wherein the latch is configured to flip when the command is transmitted on the bidirectional shared bus and further configured to pass the command as an output of the latch to the reset control circuit.

15. A method comprising:
transmitting a targeted refresh alert on a shared bidirectional bus by a memory device coupled to the shared bidirectional bus responsive to a determination by the memory device that the memory device should perform targeted refresh operations;
receiving a command on the shared bidirectional bus from a controller coupled to the shared bidirectional bus; and
performing operations per the command.

16. The method of claim 15, wherein the controller is further configured to issue a command responsive to the targeted refresh alert.

17. The method of claim 15, wherein the command is a reset command and the shared bidirectional bus is a reset bus.

18. The method of claim 15, wherein the command is a calibration command and the shared bidirectional bus is a calibration bus.

19. The method of claim 15, further comprising:
receiving a second command on a second shared bidirectional bus from the controller, wherein the controller is coupled to the second shared bidirectional bus; and
performing operations per the second command.

20. The method of claim 19, wherein the second command is a calibration command.
